(19) United States
(12) Patent Application Publication
(10) Pub. No.: US 2023/0052254 A1
(43) Pub. Date: Feb. 16, 2023

(54) DIGITAL PLATFORM FOR A DESIGN AND BUILD PROCESS

(71) Applicant: Unity Building Technologies, Inc., Walpole, NH (US)

(72) Inventor: Tedd Benson, Alstead, NH (US)

(21) Appl. No.: 17/794,634

(22) PCT Filed: Jan. 22, 2021
(86) PCT No.: PCT/US2021/014539

§ 371 Date: Jul. 22, 2022

Related U.S. Application Data
(60) Provisional application No. 62/965,403, filed on Jan. 24, 2020.

(51) Int. Cl. G06F 30/13; G06F 30/12

(52) U.S. Cl. CPC G06F 30/13; G06F 30/12

(57) ABSTRACT

A computer-aided design method for a building comprises the step of receiving, by a processor, an object to be placed in a grid that represents at least a subset of a building, the grid including a macro grid and a micro grid. The type of the object is determined by the processor. Based at least in part on determining that the type of the object is shell, the processor provides a user with the macro grid for placing the object, otherwise the processor provides the user with the micro grid for placing the object. A segment size of grid lines displayed in the macro grid is larger than the segment size of the grid lines displayed in the micro grid. The object is placed in a location in the grid based at least in part on instructions received from the user, and the grid is displayed to the user.

### CROSS-REFERENCE TO RELATED APPLICATION

This application claims the benefit of U.S. Provisional Application No. 62/965,403, filed Jan. 24, 2020, and entitled “Digital Platform for a Design and Build Process,” the content of which is incorporated herein by reference in its entirety.

### BACKGROUND

The subject matter described herein relates in general to a design and build process, and in particular to using a digital platform for a design and build process.

The modem construction era has brought about a tremendous expansion of the use of technology and computers in connection with designing and building structures of all types. Architects, for example, can use computer-aided design (CAD) to design building structures. CAD software tools enable architects to visualize structures and verify structural integrity of the structures under various conditions. CAD has also been used for floor plans to allow home buyers to determine sizes of furniture or appliances that a room will accommodate. Such CAD tools are useful to architects and home buyers. Building information modeling (BIM) software is an example of another type of tool that is often used to plan, design, construct, operate, and maintain buildings.

A variety of tools are available to automate the design and build process, and most of these tools are optimized for a particular portion(s) of the process. This results in different software tools being used in different phases of the design and build process. In some cases, links between the different products or tools are supplied by the software providers. In other cases, interfaces have to be developed and maintained by individual customers due, for example to the way that they use the tools and the data that they collect. Bridges, or links, between software products can result in translation errors and/or in data that is optimized for one phase of the construction process at the expense of other phases.

The data that is used by the automation tools is not always compatible. Different manufacturers may produce the same type of products such as bathroom sinks, however different manufacturers have sinks that are of different dimensions, and a countertop or faucet that works with one bathroom sink may not be compatible with another bathroom sink from a different manufacturer. In addition, due to the differing dimensions or other characteristics, placement of a bathroom sink, both on the floor and vertically, often differs between different manufacturers. This can result in a designer having limited ability to use products from different manufacturers in a design as products from different manufacturers are not always interchangeable. In addition, particular design and build tools may only support the use of products from a single, or limited number, of vendors. This can lead to limiting choices for customers as well as increased expense.

Accordingly, while existing tools that automate the design and build process are suitable for their intended use, the need for improvement remains, particularly in providing certainty, efficiency, and interchangeability to the design and build process.

### SUMMARY

Embodiments of the present invention are directed to a digital platform for a design and build process. A non-limiting example computer-implemented building design method includes receiving, by a processor, an object to be placed in a grid that represents at least a subset of a building, the grid including a macro grid and a micro grid. The type of the object is determined by the processor. Based at least in part on determining that the type of the object is shell, the processor provides a user with the macro grid for placing the object. Based at least in part on determining that the type of the object is infill, the processor provides the user with the micro grid for placing the object. A segment size of grid lines displayed in the macro grid is larger than the segment size of the grid lines displayed in the micro grid. The object is placed in a location in the grid based at least in part on instructions received from the user, and the grid is displayed to the user.

In addition to one or more of the features described above or below, or as an alternative, further embodiments of the method may include generating one or both of a building information model and a building production model based at least in part on contents of the grid.

In addition to one or more of the features described above or below, or as an alternative, further embodiments of the method may include that the type of the object is shell and modifying the segment size of the grid lines in the macro grid based on characteristics of the object.

In addition to one or more of the features described above or below, or as an alternative, further embodiments of the method may include that the type of the object is infill and modifying the segment size of the grid lines in the micro grid based at least in part on characteristics of the object.

In addition to one or more of the features described above or below, or as an alternative, further embodiments of the method may include that the location is between the grid lines.

In addition to one or more of the features described above or below, or as an alternative, further embodiments of the method may include that the object is selected from a library of objects that conform to specified increments of length, width, and height.

In addition to one or more of the features described above or below, or as an alternative, further embodiments of the method may include utilizing the grid to enforce one or more placement rules for the placing of the object in a location in the grid.

In addition to one or more of the features described above or below, or as an alternative, further embodiments of the method may include that the placing is further based at least in part on rules associated with one or both of the object and the grid.

In addition to one or more of the features described above or below, or as an alternative, further embodiments of the method may include that the placing is further based at least in part on a location of another object previously placed in the grid.

In addition to one or more of the features described above or below, or as an alternative, further embodiments of the method may include that an incremental hierarchy of segment sizes from the macro grid to the micro grid is specified by one or more rules.

In addition to one or more of the features described above or below, or as an alternative, further embodiments of the method may include that the object is a component with defined attributes and options, and the placing is further based at least in part on the defined attributes and options.

In addition to one or more of the features described above or below, or as an alternative, further embodiments of the method may include that the object is an element with defined attributes and options, and the placing is further based at least in part on the defined attributes and options.

In addition to one or more of the features described above or below, or as an alternative, further embodiments of the method may include that the grid is three-dimensional.

Other embodiments of the present invention implement features of the above-described method in computer systems and computer program products.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a schematic illustration of a disentanglement and layering aspect of an open build computer aided design (OBCAD) digital platform in accordance with one or more embodiments of the present invention;

FIG. 2 is a schematic illustration of component and element definitions in accordance with one or more embodiments of the present invention;

FIG. 3 depicts a block diagram of a macro grid and a micro grid in accordance with one or more embodiments of the present invention;

FIG. 4 is a block diagram of a software architecture of an OBCAD digital platform in accordance with one or more embodiments of the present invention;

FIG. 5 is a schematic illustration of components of a shell engine of the OBCAD digital platform in accordance with one or more embodiments of the present invention;

FIG. 6 is a flow diagram of a method for creating content for an elements library and a components library in accordance with one or more embodiments of the present invention;

FIG. 7 is a schematic illustration of components of an infill engine of the OBCAD digital platform in accordance with one or more embodiments of the present invention;

FIG. 8 is a flow diagram of a method for creating content for a space plans library, a rooms library, and a utilities library in accordance with one or more embodiments of the present invention;

FIG. 9 is a schematic illustration of end-user design tools and production tools of an OBCAD digital platform in accordance with one or more embodiments of the present invention;

FIG. 10 is a schematic illustration of a macro grid and macro grid rules in accordance with one or more embodiments of the present invention;

FIG. 11 is a schematic illustration of a macro grid and footprint rules in accordance with one or more embodiments of the present invention;

FIG. 12 is a schematic illustration of a micro grid and micro grid rules in accordance with one or more embodiments of the present invention;

FIG. 13 is a schematic illustration of a vertical macro grid in accordance with one or more embodiments of the present invention;

FIG. 14 is a schematic illustration of a vertical micro grid in accordance with one or more embodiments of the present invention;

FIG. 15 is a schematic illustration of a node insertion point in accordance with one or more embodiments of the present invention;

FIG. 16 is a schematic illustration of a cloud computing environment in accordance with one or more embodiments of the present invention;

FIG. 17 is a schematic illustration of abstraction model layers in accordance with one or more embodiments of the present invention; and

FIG. 18 is a schematic illustration of a computer system in accordance with one or more embodiments.

The diagrams depicted herein are illustrative. There can be many variations to the diagrams, or the operations described therein without departing from the spirit of the invention. For instance, the actions can be performed in a differing order or actions can be added, deleted or modified. Also, the term “coupled”, and variations thereof describe having a communications path between two elements and do not imply a direct connection between the elements with no intervening elements/connections between them. All of these variations are considered a part of the specification.

### DETAILED DESCRIPTION

One or more embodiments of the present invention provide an open building computer aided design (OBCAD) digital platform that can be utilized to bring certainty, efficiency, and interchangeability to the design and build process.

One or more embodiments of the OBCAD digital platform include a bi-functional three-dimensional (3D) grid that can be utilized during the design and build process to provide dimensional and positional coordination; to create interchangeable blocks, systems, and patterns; and to provide discipline to a building’s composition. The 3D grid is bi-functional because it can be used to determine both the size and the location of objects in order to provide designers with both restrictions and flexibility in order to design buildings that allow the buildings to be more easily buildable. These buildings can include, but are not limited to, buildings that are manufacturable in a pre-fabrication environment. Along with the underlying discipline provided by the volumetric (or 3D) grid, one or more embodiments of the present invention also include a library of integrated building assemblies having engineering, production and performance detail. The integrated building assemblies can be used to create object-oriented design functionality and to elaborate on the consequences of different design choices.

One or more embodiments of the bi-functional 3D grid is both dimensional and positional. A 3D grid is dimensional in that it can enforce standard increments for the length, width, and height of building objects. The 3D grid is positional in that it can enforce standard placement rules for the positioning of building objects. The 3D grid is used to create a design environment which controls the standardizing of spatial dimensions and component dimensions, as well as positional locations. The libraries and templates of objects organize the standard dimensions and the software logic ensures, through smart nodes, that the placements of objects snap to positions based on rules associated with the objects and/or grids. As used herein the term “smart node” refers to intelligent reference information connected to a building object, such as a building component, for automating the necessary adjustment of component dimensions, as well as restricting and automating decisions to only the correct position options for each particular component. The standard, or specified, increments and placement rules can be implementation specific and may vary based on the type of building or structure being designed, different measurement systems in different countries, and/or based on different country or state building code requirements.

In accordance with one or more embodiments of the present invention, the distance between the grid lines (or segment size) in the 3D grid can vary depending on the type of objects (e.g., shell, infill) that are being placed in the grid. The 3D grid can include a macro grid with a larger distance, or segment size, between grid lines (e.g., segments of two feet, four feet, etc.) for controlling placement of objects that are part of the “shell” (i.e., structure and enclosure elements of walls, floors, and roofs of a building) and one or more micro grids with a smaller distance between grid lines (e.g., segments of one foot, six inches, three inches, etc.) for controlling dimensions and placement of infill objects, such as components within the shell of the building. Objects that are within the shell of the building include items that are part of the shell such as, but not limited to windows, doors, and skylights. Objects that are within the shell of the building can also include items that are enveloped by the shell such as, but not limited to interior walls, stairs, and mechanical systems.

One or more embodiments of the present invention includes specific rules that govern “regression” which can include an incremental hierarchy from the macro grid or micro grid dominate dimensions into lower increments, or distances between grid lines. Regression rules can require users to default to the largest possible grid size for the structure components (macro grid) or infill components (micro grid) and spatial patterns but use a logical regression in ½ (half) increments (e.g., from 2 feet to 1 foot to 6 inches to 3 inches, etc.) if a smaller dimension is needed for placing the object. Embodiments are not limited to the described rule of halves and any rules that avoid dimensional chaos may be utilized.

One or more embodiments of the OBCAD digital platform described herein provides margin management. Margin management refers to the ability for objects to be placed at increments between grid control lines. In one or more embodiments, the margin between the ideal and actual dimensions/placements can be held unoccupied by other objects.

One or more embodiments of the OBCAD digital platform described herein provides a separation between shell and infill engines that leverages disentanglement (e.g., the decoupling of a building’s exterior structure from the other aspects of the building). As used herein, the term “shell” refers to objects that include structure and enclosure elements of walls, floors and roofs of a building, including structural openings for stairs or other architectural considerations. A shell can include both structural and non-structural elements. As used herein, the term “infill” refers to objects that include the interior systems of the building such as, but not limited to interior partitions, cabinets, finishes, and the heating, ventilating, cooling, electrical and plumbing components. Infill can also include finishes or accessories attached to the exterior walls or the roof. In accordance with one or more embodiments of the present invention, any object which does not have a type of shell is considered to be an infill type object. Embodiments are not limited to two types of objects, and in one or more other embodiments of the present invention there are three or more types of objects all corresponding to different segment sizes within the grid.

One or more embodiments of the OBCAD digital platform provide insert nodes which are the datum points to which objects are positioned and fitted into a Building Production Model (BPM). The BPM is alternately referred to as a Building Action Model (BAM). Every element or component can have a virtual node (or two nodes). For example, a stair could have a node at the middle of the last riser for how it fits into an opening and it also could have a side node for its width. Nodes pair with the environment into which the component containing the nodes is placed and in one or more embodiments are used to control positions and dimensions for the automated generation of BPMs.

As used herein, the term BPM refers to a 3D CAD model containing not only information relating to the real-world objects contained therein (e.g., a building information model or “BIM”), but also information needed to manufacture aspects of the building, including componentizing, sub-assembling, and assembling. A BIM provides digital information that is used as a basis for automated production of building components. A BAM, or BPM, includes digital information for the production actions that have to do with a building’s construction. It also provides digital instructions that are sent to the construction environment. For example, a BAM, or BPM, can be sent to machines, robots, enterprise resource planning (ERP) systems, etc. in the construction environment.

One or more embodiments of the OBCAD digital platform includes libraries of building components, assemblies, or systems such as, but not limited to, digital representation data and/or algorithms that can be aggregated to build a complete digital composition of the intended BPM. The information in the libraries can be used to provide information about the consequences of design choices and to create the desired design aesthetics, performance, cost, and functionality as the outcome of the design and build process.

One or more embodiments of the OBCAD digital platform described herein is implemented using computer hardware and/or computer software. The software architecture of the OBCAD digital platform can include interconnected but separate levels of usage, mediated by a configurable implementation. There can be different and/or separate functionality that connects to a central database for creation, configuration, and production. The different levels of functionality can be based on user needs. Different user types (e.g., product manufacturer, architect, off-site manager, builder, developer, owner) can engage with the software at different levels. In some embodiments, different user types are allowed access to certain levels of functionality and/or user interfaces as determined by the particular implementation or platform.

In accordance with one or more embodiments of the present invention, the levels of functionality include the design of specific building materials which can be input to the design of building components, and building components can be input to the design of a shell object or of an infill object. The shell or infill objects can be used as input to the design of a whole or partial building exterior footprint or interior rooms, which can then be input to the design of a building. At each of these levels, there can exist a configurable gate whereby certain instantiations, users, or user types, depending on the particular platform implementation, can be allowed to move to the next level or alternatively the next level is kept hidden. This can allow OBCAD versions specific to the business and marketing needs of each implementer, differentiation between different implementers, and management of intellectual property (IP) and confidentiality from different content providers using the platform.

The OBCAD platform provides design and production tools that allow users (e.g., developers, architects, builders, prefabricators, etc.) to design buildings and structures using pre-configured objects and models. The OBCAD platform separately provides templates, objects and models for various building systems, as well as multi-scale CAD environments (grids) based on standardized building product sizes and architectural dimensions, and rules regarding relative positions and orientations of objects and building systems.

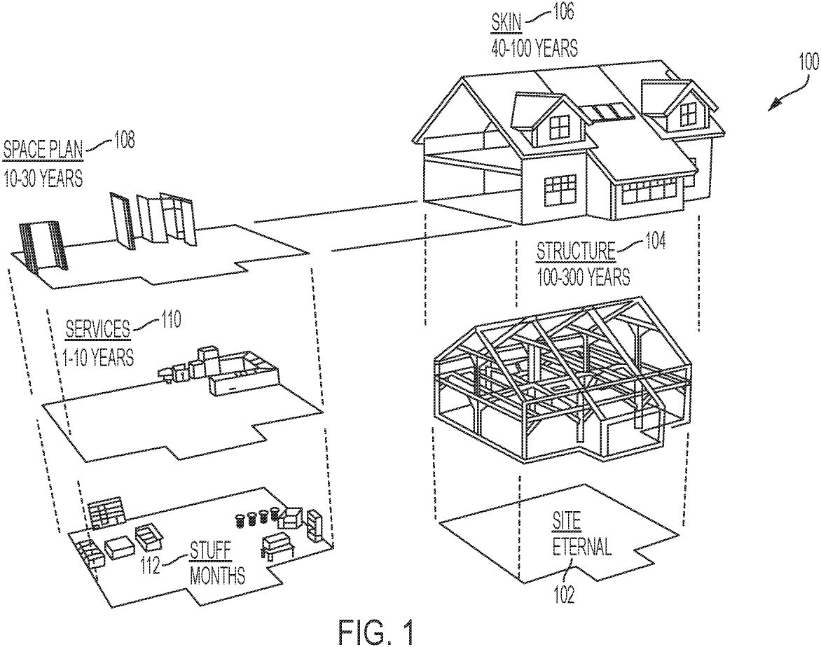

Turning now to FIG. 1, a schematic illustration 100 of aspects of an OBCAD digital platform is generally shown in accordance with one or more embodiments of the present invention. The schematic illustration 100 of FIG. 1 shows a separation, or disentanglement, of the different building systems from each other such that each can change (both during initial design and in renovation) independently from one another. As shown in FIG. 1, a building site 102 may last forever, a building structure 104 may last one hundred to three hundred years, a building skin 106 forty to one hundred years, a building space plan 108 ten to thirty years, building services 110 one to ten years, and the lifespan of the stuff 112 within the building (e.g., furniture) can often be measured in months. One or more embodiments of the OBCAD digital platform described herein supports the design and construction of a building that allows the different building systems to change independently from each other during the life of the building (e.g., during initial design and in renovation).

As used herein, the term “building” refers to any structure such as, but not limited to all or a portion of a shed, a house, an apartment building, an office building, a retail location, and/or an entertainment venue. The building systems shown in FIG. 1 are just one example of a way to group the different portions of a building and one or more embodiments of the present invention support other groupings of building systems. For example, the skin 106 may be broken into two system such as items that are part of the shell and items that are enveloped by the shell, and/or two of the building systems shown in FIG. 1 may be consolidated into a single building system.

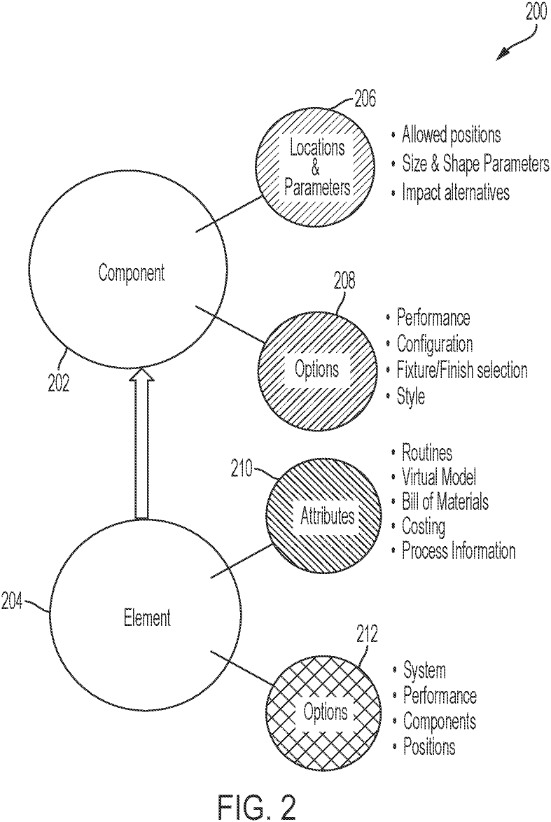

Turning now to FIG. 2, a schematic illustration 200 of components and elements are generally shown in accordance with one or more embodiments of the present invention. As used herein, the term “element” 204 refers to an object made up of an aggregation of one or more subset parts and/or systems. Attributes 210 of an element 204 can include, but are not limited to routines, virtual models, bill of materials, costing, performance, and/or process information. Options 212 of an element 204 can include, but are not limited to systems, performance, composition (e.g., materials and assemblies), and/or positions.

As used herein, the term “component” 202 refers to an aggregation of elements 204 and systems, and it may be characterized by a fixed geometry, a variable finish, and material options. Locations and parameters attributes 206 of a component 202 can include, but are not limited to allowed positions, size and shape parameters, and/or impact alternatives. Options 208 of a component 202 can include, but are not limited to performance, configuration, fixture/finish selection, and/or style.

As used herein, the term “characteristics of an object” refers to one or more attributes 206 210 and/or options 208 212 of a component 202 and/or element 204. An object can be a component 202 or an element 204.

As used herein, the term “system” can refer to a functional system such as, but not limited to exterior walls, interior walls (e.g., sound isolation walls or demising walls), stairs, cabinets, and/or storage. The term “system” can also refer to a mechanical system such as, but not limited to an electrical system (e.g., plug and appliance, lighting, low voltage), plumbing (drainage, supply), and /or a heating ventilation, and air conditioning (HVAC) system. The term “system” may refer to all or a portion of an element 204 or of a component 202.

In accordance with one or more embodiments of the present invention, an element 204 is 2D and a component 202 is 3D. Examples of elements 204 include but are not limited to floor panels, wall panels, roof panels and their requisite subassemblies, such as sheathing layers, framing assemblies, and insulation systems. Examples of components 202 include but are not limited to composition building volumes with various potential geometries, such as primary rectilinear or curvilinear structures, add-on sub-volumes, roof volumes with myriad shape possibilities, dormers, and other volumetric creations from assembled elements 204.

As used herein, the term “composition” refers to an aggregation of components 202 with configuration parameter attributes 206 and options 208. A composition may represent be an entire building or a subset of a building.

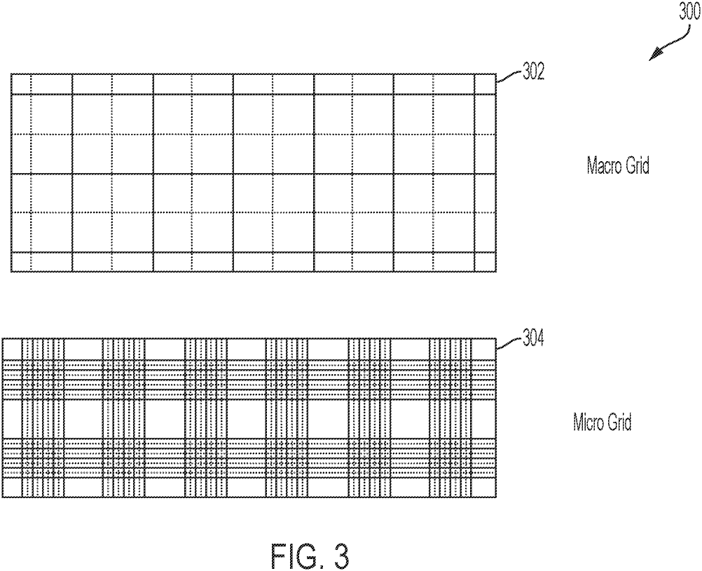

Turning now to FIG. 3, a block diagram 300 of a macro grid (MaG) 302 and a micro grid (MiG) 304 are generally shown in accordance with one or more embodiments of the present invention. One or more embodiments of the present invention provide disentanglement by establishing a multi-scale, 3D grid (e.g., based on standard building product sizes and architectural/human dimensions) to which all features from the front door to a light switch, must adhere in placement and dimensions during the design process. Embodiments of the OBCAD digital platform utilize macro grids 302 and micro grids 304 that are compatible with each other such that functionally or physically connected building features are always in an appropriate, compatible location, regardless of where that location is. The grids are the semantics that ensure compatibility between the otherwise disentangled systems.

The macro grid 302 and the micro grid 304 are referred to herein collectively as an “OBGrid” or “grid.” The grid forms the basis for cross-industry standardization, allowing integration of disparate materials, parts, fixtures, etc. into components and elements that can be manufactured and installed with better consistency and fewer defects, while reducing waste and cost. With macro and micro dimensional standards, many industry players can integrate their products into components and elements that can confidently and efficiently be assembled into complete buildings of all types. In the embodiment shown in FIG. 3, the macro grid 302 is the dominant grid and it controls the space plan footprint (e.g., interior dimensions (IDs), center line (CL), and edge positions). In the embodiment shown in FIG. 3, the micro grid 304 controls the space plan and infill components (e.g., edge or CL positions).

In accordance with one or more embodiments of the present invention, when dimensional standards conflict with specific issues and the standards are difficult to use or are not beneficial, the system allows the possibility of identifying “non-modular zones” while adhering to the grid standards in the remaining building areas.

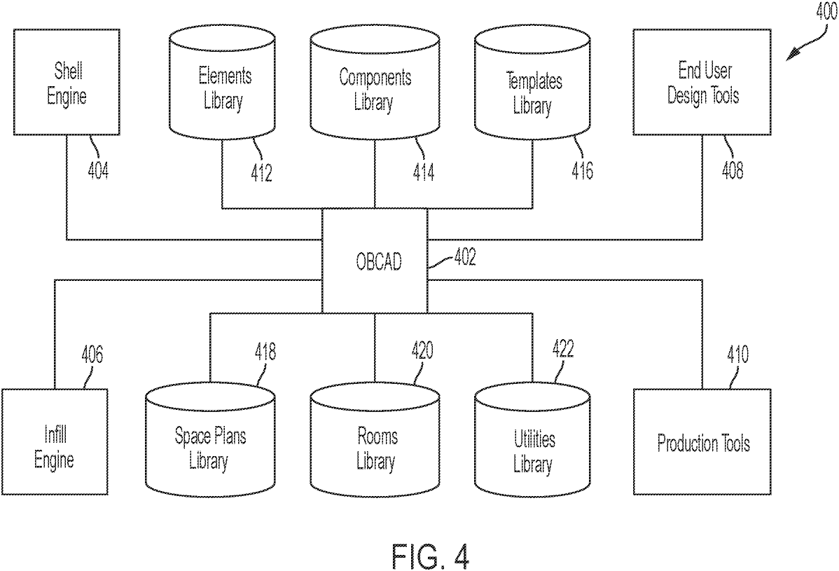

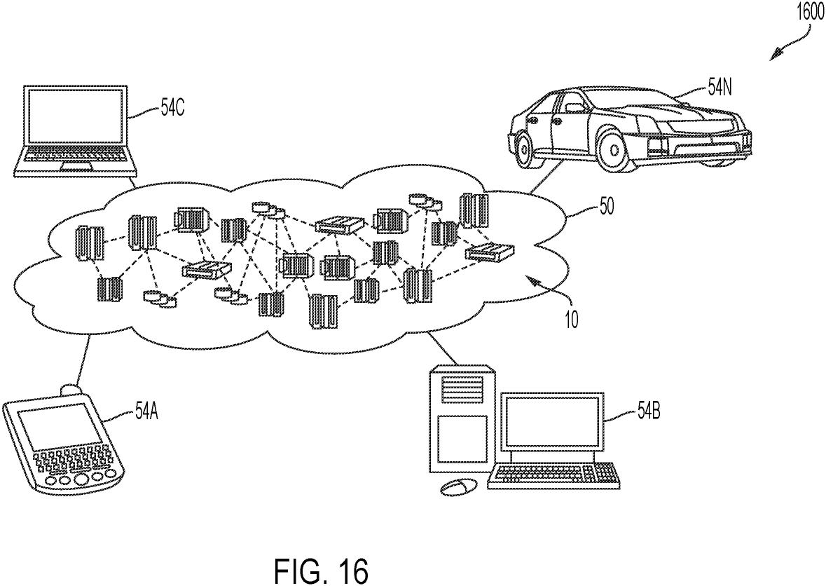

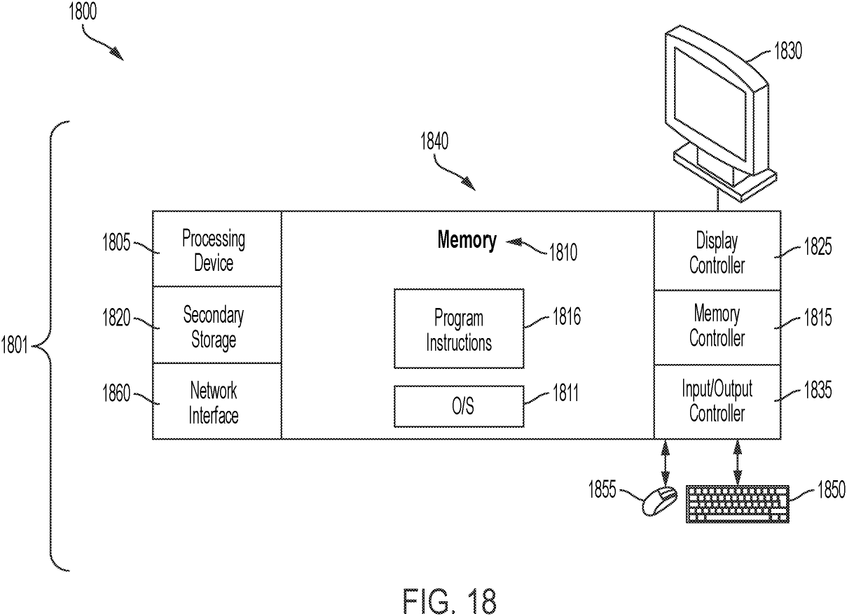

Turning now to FIG. 4, a block diagram 400 of components of an OBCAD digital platform is generally shown in accordance with one or more embodiments of the present invention. All or a portion of the digital platform shown in FIG. 4 may be controlled or executed by all or portion of computer 1801 of FIG. 18 and/or by any other suitable processing device or computer system, such as a cloud computing node 10 of FIG. 16. The OBCAD digital platform provides design and production tools that allow users (e.g., homeowners, designers, developers, architects, builders, prefabricators, etc.) to design buildings and structures using pre-configured objects and models. The OBCAD platform separately provides templates, objects and models for various building systems, as well as multi-scale CAD environments (grids) based on standardized building product sizes and architectural dimensions, and rules regarding relative positions and orientations of objects and building systems.

The OBCAD digital platform shown in FIG. 4 includes OBCAD software 402 which includes a shell engine 404, an infill engine 406, end user design tools 408, and production tools 410. The shell engine 404 can be used, along with templates from the templates library 416, to populate the elements library 412 and components library 414 with building objects (e.g., from various manufacturers). The infill engine 406 can be used, along with templates from the templates library 416, to populate the space plans library 418, rooms library 420, and utilities library 422 based on products available from various vendors. The end-user design tools 408 allow a user (e.g., a homeowner, designer, developer, etc.) to design features of a home or other structure to be built. The end-user design tools 408 support the design process using content of the various libraries populated by the shell engine 404 and/or the infill engine 406. The production tools 410 can be used, for example, by a manufacturer (e.g., builder of a conventional or prefabricated home) to facilitate construction of building structure. Contents of the libraries shown in FIG. 4 can be stored in any manner known in the art with one or more copies of all or a portion of the libraries spread across one or more logical or physical storage devices and/or geographic locations.

In an embodiment, the OBCAD digital platform includes one or more design engines, such as a shell engine 404 and an infill engine 406. Each engine includes design workstations employed, for example, by an implementation expert to design different aspects of a building. A workstation may be a software component, such as an interface or module that a user can interact with and may be used at individual client computers (e.g., as physical workstations). Each design workstation can have its own libraries to use as the building blocks of that building aspect. Each engine may also have a template design workstation, used by content creators to populate design workstation libraries with building blocks. Each design workstation may have its own template library or libraries that hold all of the extant building blocks. In embodiments, not all extant building blocks are revealed in the design workstations for all software implementations, for all users, at all times; this is dependent on what the software administrator makes visible to the software user in the design workstations.

It is to be understood that the schematic illustration of FIG. 4 is an example of one embodiment of the OBCAD digital platform and is not intended to indicate that the OBCAD digital platform must include all of the components shown in FIG. 4. Rather, the OBCAD digital platform can include any appropriate fewer or additional components not illustrated in FIG. 4. In addition, the contents of the components can be arranged differently. All or a subset of the components shown in FIG. 4 can be located in different geographic locations and/or managed by different computer systems. The components can communicate with each via any manner known in the art including via a network such as other via any network known in the art such as network 50 of FIG. 16. Furthermore, it is to be understood that the OBCAD digital platform shown in FIG. 4 is provided for illustration purposes and is not intended to be limiting. Embodiments described herein apply to any CAD or other computer-based design or modelling system.

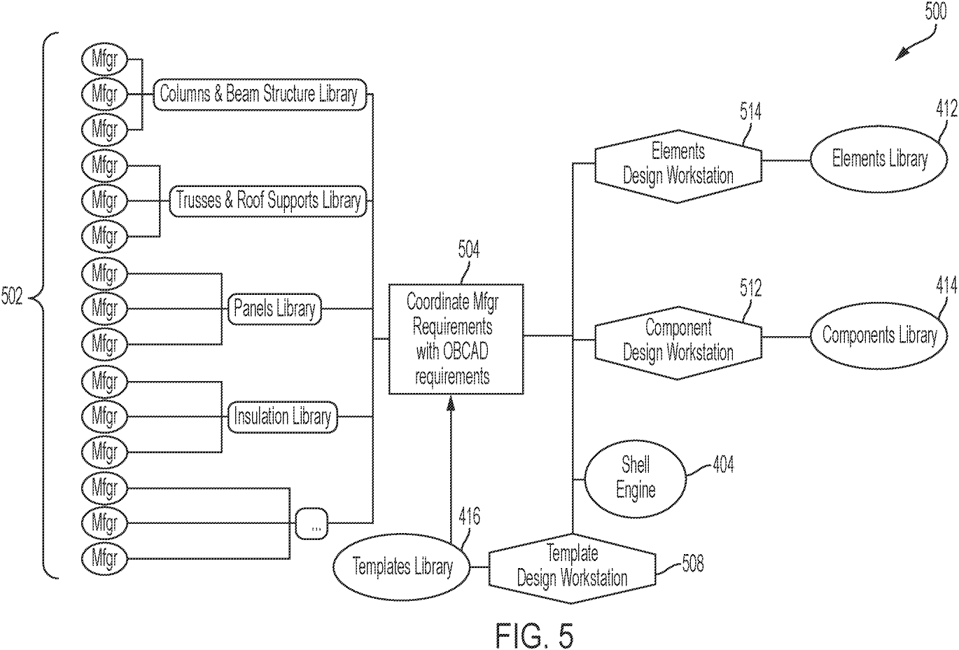

Turning now to FIG. 5, a schematic illustration 500 of components of a shell engine 404 of the OBCAD digital platform is generally shown in accordance with one or more embodiments of the present invention. All or a portion of the digital platform shown in FIG. 5 may be controlled or executed by all or portion of computer 1801 of FIG. 18 and/or by any other suitable processing device or computer system, such as a cloud computing node 10 of FIG. 16. As shown in FIG. 5, libraries 502 of materials and parts for shells (e.g., elements and components) are received from manufacturers or other vendors and are used to create element and component building blocks through an interface with dimensional standardization templates in templates library 416. As shown in the example of FIG. 5, the materials and parts that are received from vendors are related to columns and beam structures, trusses and roof supports, panels, and insulation.

At block 504, the materials and parts from the vendors are coordinated with OBCAD requirements as specified by templates in templates library 416. The coordinating at block 504 may be performed automatically by one or more of computer instructions and/or a user at template design workstation 508. In the example shown in FIG. 5, the templates library 416 includes templates for columns and beam structures, trusses and roof supports, panels, and insulation. Templates for different types of products may be generated by a user at template design workstation 508, with each template specifying acceptable dimensions as well as placement rules for the corresponding product. In the case of exterior wall panels, for example, the templates set the dimension options as well as the allowable locations of subelements (e.g., windows and doors), rules for attachment extensions, and other standardized functional requirements.

Once a material or part conforms with the OBCAD requirements, it can be used by content creator users at component design workstation 512 and/or elements design workstation 514 to generate object building blocks that are stored in elements library 412 and components library 414.

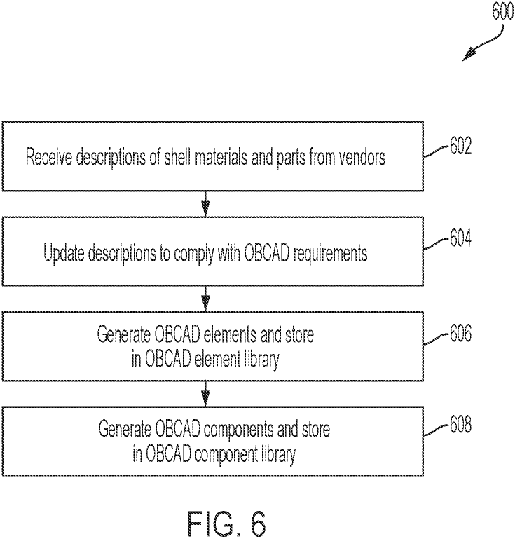

Turning now to FIG. 6, a flow diagram of a method 600 for creating content for elements library 412 and components library 414 is generally shown in accordance with one or more embodiments of the present invention. All or a portion of the processing shown in FIG. 6 can be performed by components of the shell engine 404 of FIG. 5.

At block 602, descriptions of shell materials and parts are received from manufacturers and other vendors (e.g., via the libraries 502 of FIG. 5), and at block 604, the descriptions are updated to comply with OBCAD requirements. In one example, descriptions from the vendors that are received at block 602 are for framing materials to be aggregated into a structural panel assembly. The received descriptions are updated at block 604 so that they include sufficient information to ensure that the parts can be organized into complete panels in compliance with OBCAD standard dimension options. At block 606, the compliant framing parts are combined with other compliant panel assembly parts (sheathing, insulation, etc.) to generate OBCAD elements for storage in elements library 412.

In accordance with one or more embodiments of the present invention, a panel template stored in the templates library 416 specifies the allowable standardized dimensional constraints in conformance with OBCAD rules. Based on the contents of the template, the description from the vendor is updated at block 604 by a user at an elements design workstation 514 to include the potentially unique assemblies in OBCAD standardized dimensions. The user may also add options 212 such as unique thermal or acoustic characteristics and attributes 210 such as the bill of materials for the manufacturer or performance and cost options for the consumer. At block 606, the updated description is stored in elements library 412.

An example of a description about a vendor’s panel product includes all of the associated options 212 and attributes 210. A panel product template stored in the templates library 416 specifies the OBCAD conformance rules. Based on the contents of the template, the description from the vendor is updated at block 604 by a user at a component design workstation 512 to include allowable component positions and interface requirements. The user may also add options 208 to the description such as thermal performance, cladding choices, fixture choices, as well as attributes 206, such as specific geometry and allowable locations. At block 608, the updated description is stored in components library 414.

The process flow diagram of FIG. 6 is not intended to indicate that the operations are to be executed in any particular order, or that all of the operations shown in FIG. 6 are to be included in every case. Additionally, the processing shown in FIG. 6 can include any suitable number of additional operations.

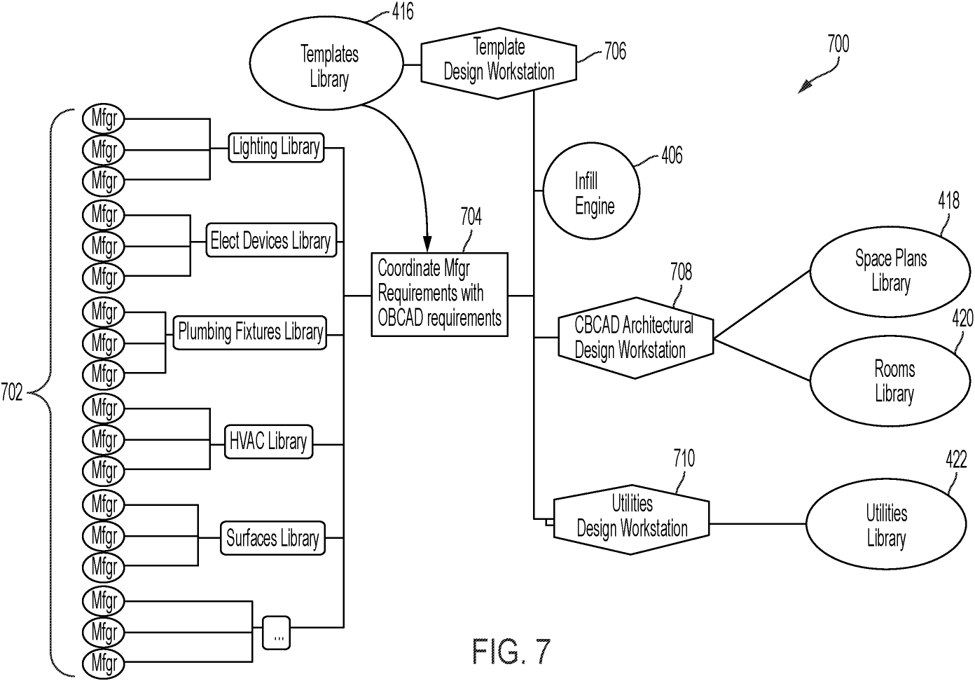

Turning now to FIG. 7, a schematic illustration 700 of components of an infill engine 406 of the OBCAD digital platform is generally shown in accordance with one or more embodiments of the present invention. All or a portion of the infill engine 406 may be controlled or executed by all or portion of computer 1801 of FIG. 18 and/or by any other suitable processing device or computer system, such as a cloud computing node 10 of FIG. 16. As shown in FIG. 7, libraries 702 of materials and parts for infills (e.g., elements and components) are received from manufacturers or other vendors and used to create infill element and component building blocks through an interface with dimensional standardization templates in template library 416. As shown in the example of FIG. 7, the materials and parts that are received from vendors are related to lighting, electrical devices, plumbing fixtures, HVAC, and surfaces. At block 704, the materials and parts from the vendors are coordinated with OBCAD requirements as specified by templates in the templates library 416. The coordinating at block 704 may be performed automatically by one or more of computer instructions and a user at template design workstation 706.

In the example shown in FIG. 7, the templates library 416 includes templates for lighting, electrical devices, plumbing fixtures, HVAC, and surfaces. Templates for different types of products may be generated by a user at template design workstation 706, with each template specifying acceptable dimensions as well as placement rules for the corresponding product. In one example, the template for electrical fixtures specifies allowable positions for outlets and switches based on OBCAD microgrid positional rules. Users can choose positions that comply with building code requirements and/or functional preferences.

Once a material or part conforms with the OBCAD requirements, it can be used by content creator users at OBCAD architecture design workstation 708 and/or utilities design workstation 710 to generate building blocks that are stored in the space plans library 418, rooms library 420, and utilities library 422. In accordance with one or more embodiments of the present invention, different infill products are received from manufacturers and used to aggregate with other materials and parts to create complete assemblies as elements and components. In an embodiment, the assemblies are then defined as sub-assemblies (plumbing walls, demising walls, etc.) or rooms (kitchens, bathrooms, closets, etc.). The sub-assemblies and rooms are added to libraries that can be utilized in designs by other users.

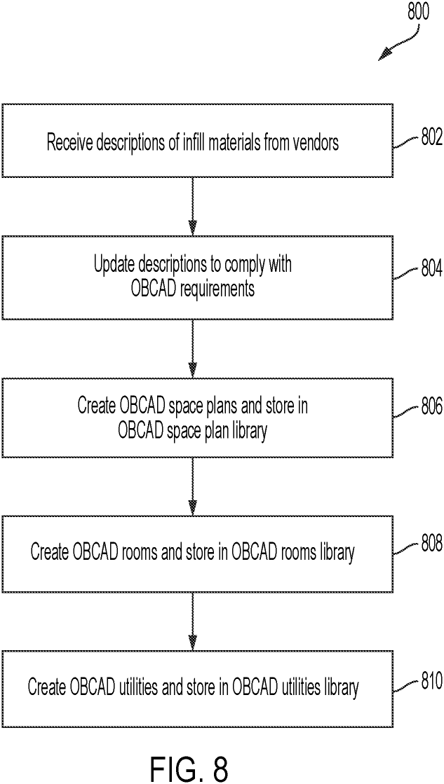

Turning now to FIG. 8, a flow diagram of a method 800 for creating content for space plans library 418, rooms library 420, and utilities library 422 is generally shown in accordance with one or more embodiments of the present invention. All or a portion of the processing shown in FIG. 8 can be performed by components of the infill engine 406 of FIG. 7.

At block 802, descriptions of infill materials and parts are received from manufacturers and other vendors, and at block 804, the descriptions are updated to comply with OBCAD requirements. Descriptions of materials and parts that are aggregated and configured into functional space plans (e.g., bathroom plumbing fixtures, cabinets, and functional accessories organized into configuration options) are updated at block 806 by a user at an OBCAD architectural design workstation 708 and stored in space plans library 418. In the bathroom example, a vanity sink in block 802 would be checked with plumbing supply options at block 804 to ensure allowable viable micro grid positions, as a part of complete bathroom configurations that are created at block 808 that comply with the OBCAD infill micro grid dimensional rules. The configured and approved bathrooms are stored in the OBCAD rooms library 420.

At block 810, descriptions of materials and parts that are related to utilities (such as plumbing supply, drainage, ventilation ducting, electrical conduits, etc.) are updated by a user at a utilities design workstation 710 and stored in utilities library 422. An example includes a vanity sink from a manufacturer that can be located in alignment with the micro grid positions specified by the OBCAD requirement to ensure that the plumbing supply and drainage assembly standards can be deployed in to ensure the fixture is properly connected to supply and drainage.

The process flow diagram of FIG. 8 is not intended to indicate that the operations are to be executed in any particular order, or that all of the operations shown in FIG. 8 are to be included in every case. Additionally, the processing shown in FIG. 8 can include any suitable number of additional operations.

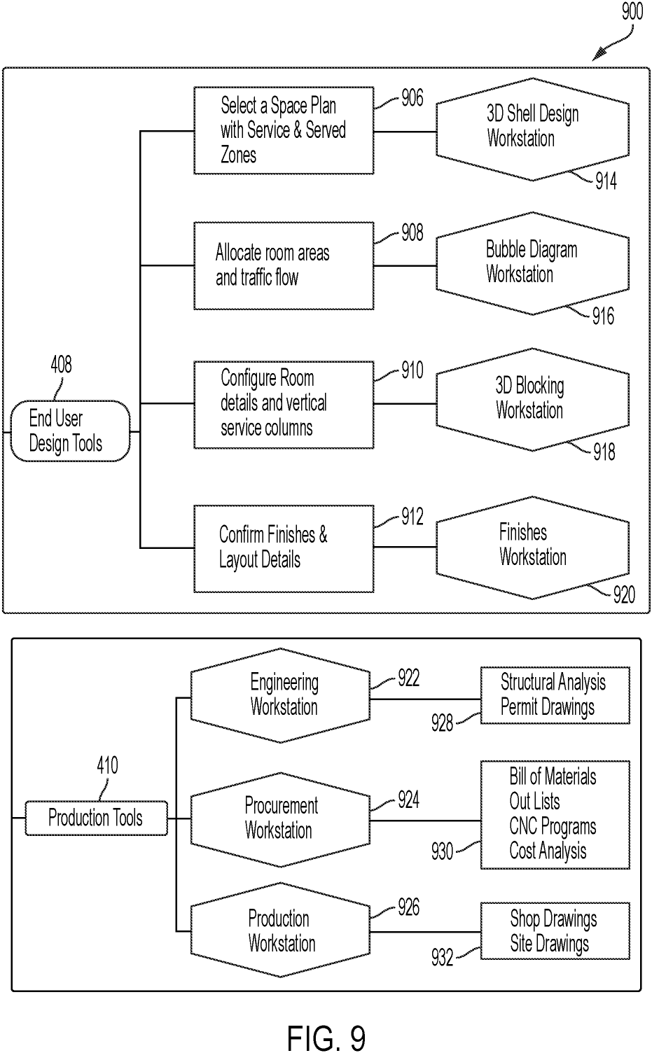

Turning now to FIG. 9, a schematic illustration 900 of end-user design tools 408 and production tools 410 of an OBCAD digital platform is generally shown in accordance with one or more embodiments of the present invention. As shown in the embodiment of FIG. 9, the end-user design tools 408 and the production tools 410 are two separate user interfaces that grant non-experts (e.g., homeowners) access to a specific implementation of the OBCAD digital platform. In an embodiment, the end-user design tools 408 include the set of functions used by homeowners and developers to design/configure a home or other building to be built. The end-user design tools 408 have access to contents of elements library 412, components library 414, space plans library 418, rooms library 420, and/or utilities library 422. The functions and data available to the homeowners and developers can be modified based on implementation requirements. In an embodiment, the production tools 410 include a customized set of functions used by the staff of a prefabrication factory or builder. As an example, it may be important that the end-user design tools 408 used by homeowners and developers allow full creation of compositions, which can then be delivered to production participants with added data to allow efficient and accurate manufacturing. The data files in the end user design tools 408 allow viewers to see digital representations of the intended building and access product, system, and cost information; the data files in the production tools have much of the same information, but may also include information for advanced tooling fabrication and construction sequencing.

The end-user design tools 408 shown in the embodiment in FIG. 9 include a 3D shell design workstation 914 executing computer instructions to select a space plan with service and served zones 906; a bubble diagram workstation 916 executing computer instructions to allocate room areas and traffic flow 908; a 3D blocking workstation 918 executing computer instructions to configure room details and vertical service columns 910; and a finishes workstation 920 executing computer instructions to confirm finishes and layout details 912. In accordance with one or more embodiments of the present invention, the end-user design tools 408 provide a design process that includes displaying a grid on a user interface and allowing a user to place objects from the libraries into the grid subject to the rules and constraints described herein.

The production tools 410 shown in the embodiment in FIG. 9 include an engineering workstation 922 executing computer instructions for performing structural analysis and generating permit drawings 928; a procurement workstation 924 executing computer instructions for generating bill of materials, cut lists, and cost analysis 930, and that also includes CNC programs; and a production workstation 926 executing computer instructions for generating shop drawings and site drawings 932.

It is to be understood that the illustration of the end-user design tools 408 and production tools 410 shown in FIG. 9 is an example of one embodiment of the present invention and is not intended to indicate that the end-user design tools 408 and production tools 410 must include all of the components shown in FIG. 9. Rather, the end-user design tools 408 and production tools 410 can include any appropriate fewer or additional components not illustrated in FIG. 9. In addition, the contents of the tools can be arranged differently and all or a subset may be located in different geographic locations.

One or more embodiments of the present invention support different roles in the design and build process. These roles can include but are not limited to a software platform developer/licensor, an implementor, a software administrator, an implementation expert, and/or end-users. In accordance with one or more embodiments, different end-users can have access to different elements of the OBCAD digital platform. For example, in accordance with one or more embodiments, a building product manufacturer is able to create library components or systems, while an architect is able to create catalog designs using the library of components, systems, and other products brought into the OBCAD system by other players. In turn, homeowners are able to build their personal compositions based on the available designs and the library options selected by the architect or other professional designers.

One or more embodiments of the OBCAD digital platform connects all participants in the construction value stream, including firms that compete directly with each other. One or more embodiments of OBCAD digital platform are content agnostic, that is they can contain (and if desired reveal to the user) building products, components (e.g., sub-assemblies), designs, and rules from numerous sources. Because it is not always desirable to reveal all possible options to a particular user or user group, in one more embodiment of the present invention what is known to whom is based on two structures: software implementation and user role. Segregation of user roles allows participants to use the functionality needed for their role without the need or obligation to interact with other OBCAD role players and their particular system contributions or uses. For example, what is known to a particular user can be based on whether they are the future building owner, a subcontractor, the prefabrication factory, the builder, the architect, the developer, the software administrator, etc.

One or more embodiments of the present invention can be licensed to a wide range of licensees each having their own business needs. For example, a developer may want to limit house sizes and colors, an architect may want to limit building designs to their own building designs and their preferred wall assemblies, a builder may only want to use products from preferred vendors, and a prefab factory may only want to use specific details. Who has access to what in each of these roles can be defined at the software implementation level.

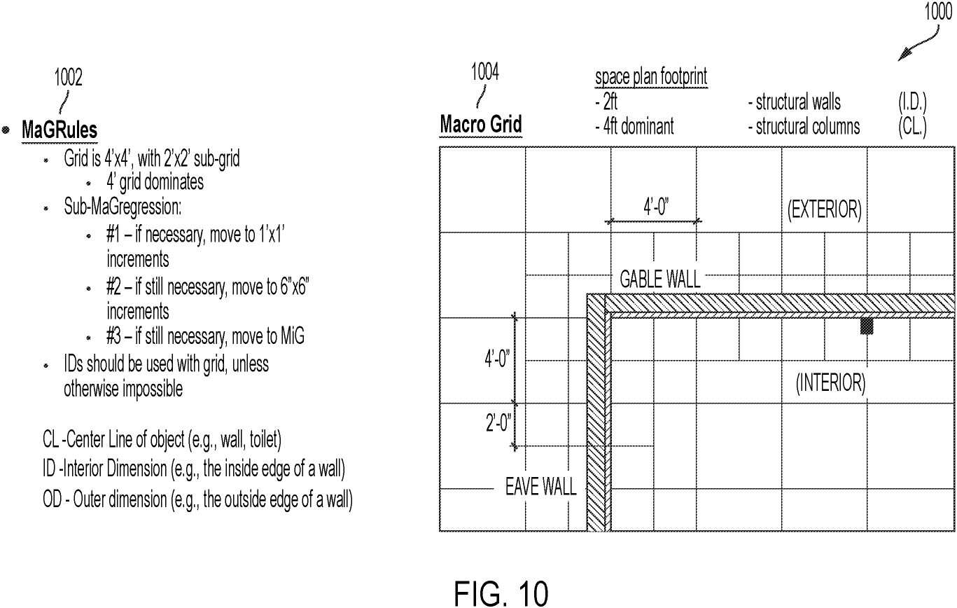

Turning now to FIG. 10, a schematic illustration 1000 of a macro grid 1004 and macro grid rules 1002 for a space plan footprint is generally shown in accordance with one or more embodiments of the present invention. The macro grid 1004 shown in FIG. 10 may be displayed to a user for placing objects when designing a space plan using one of the end user design tools 408. The embodiment shown in FIG. 10 uses a macro grid 1004 that is four feet by four feet with sub-grids of two feet by two feet, one foot by one foot, and six inches by six inches. In accordance with one or more embodiments of the present invention, it may be “necessary” to move to a different grid increment size when, for example, a zoning setback requirement for a building lot might suggest the need for a “finer” grid dimension than the macro grid basis. In another example, the macro grid of a subset volume might have to be reduced to avoid an interference with an adjacent door or window.

Embodiments are not limited to grids having the dimensions shown in FIG. 10 as any other dimensions can also be implemented by exemplary embodiments. For example, the macro grid may be ten feet by ten feet, or six feet by six feet, or five feet by five feet, forty inches by forty inches, three feet by three feet or any other dimension, with sub-grids having dimensions that are half those of the macro grids. For example, if the micro grid is forty inches by forty inches, its corresponding sub-grids may be twenty inches by twenty inches, ten inches by ten inches, and five inches by five inches. In addition, more or fewer than three levels of sub-grids may be implemented by one or more embodiments of the present invention. Further, the grid dimensions (also referred to as grid increments) may be specified in metrics measurements. The grid rules depicted in FIG. 10 illustrate example dimensional rules for all primary footprints and subset component footprints created in 512 workstation that are stored in components library 414.

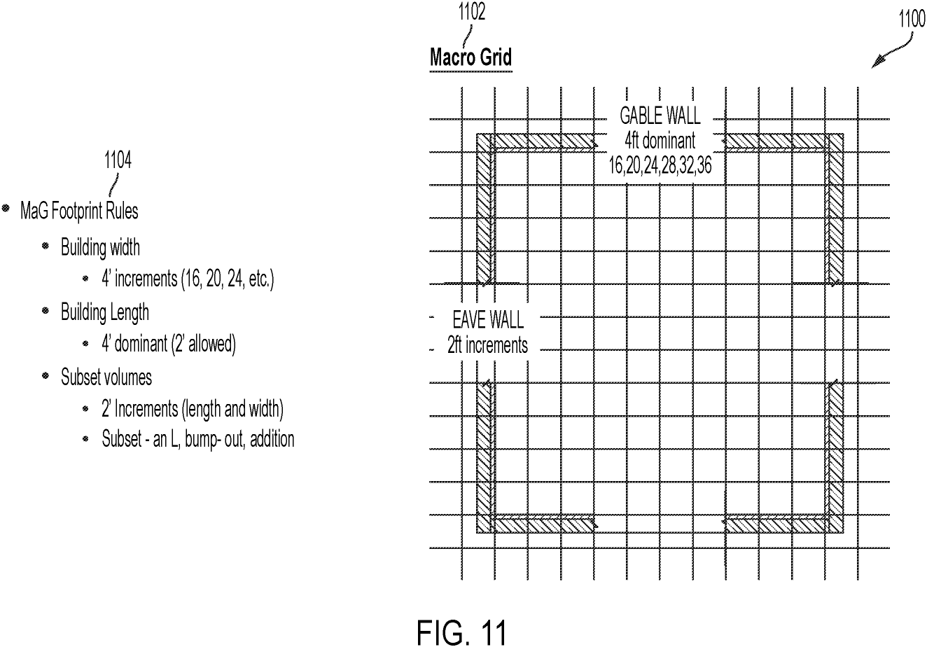

Turning now to FIG. 11, a schematic illustration 1100 of a macro grid 1102 and footprint rules 1104 is generally shown in accordance with one or more embodiments of the present invention. The macro grid 1102 shown in FIG. 11 may be displayed to a user for placing objects during building design when using one of the end user design tools 408. In accordance with one or more embodiments of the present invention, the footprint rules 1104 are used to determine primary base building dimensions and secondary dimensions for additions or insets.

The embodiment of the footprint rules 1104 shown in FIG. 11 include: building width on four foot increments; building length to prioritize four foot increments, however two foot increments are allowed; and subset volumes - two foot increments for lengths and widths. As shown in the embodiment of the footprint rules 1104 in FIG. 11, a subset is an “L”, a “bump-out”, or an “addition.” The specific increment values shown in FIG. 11 are intended as examples only, as any increment value can be implemented by one or more embodiments of the present invention. The primary and subset footprints govern the allowable components in the space plan library 418 and are configured into building compositions at the architectural design workstation 708.

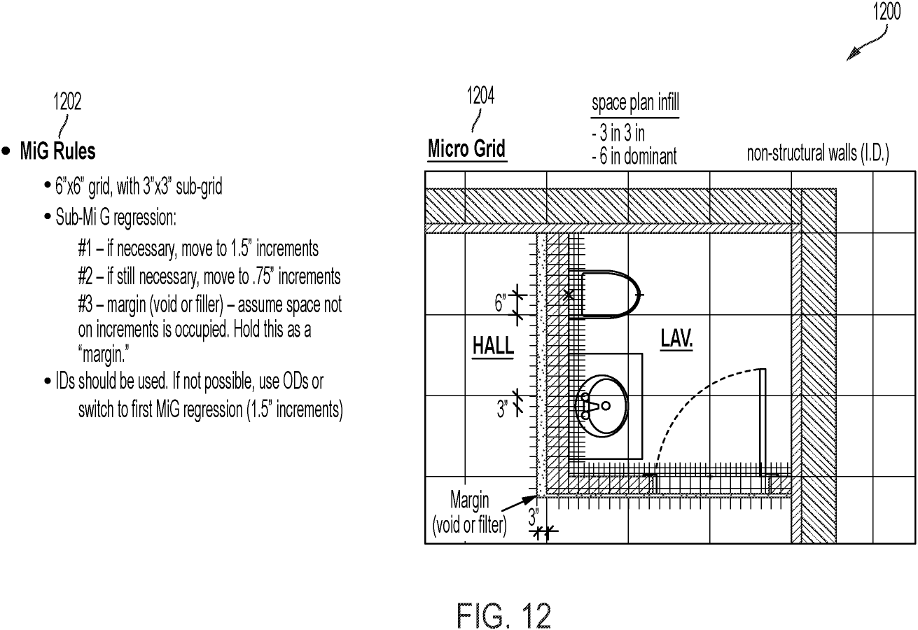

Turning now to FIG. 12, a schematic illustration 1200 of a micro grid 1204 and micro grid rules 1202 for a space infill plan is generally shown in accordance with one or more embodiments of the present invention. The micro grid 1204 shown in FIG. 12 may be displayed to a user for placing objects when designing a space plan infill (e.g., a bathroom) using one of the end user design tools 408. In accordance with one or more embodiments of the present invention, it may be “necessary” to move to a different grid increment size when, for instance, finish components such as doors, cabinets, built-ins, etc. need a smaller dimensional increment in order to have an appropriate fit tolerance.

FIG. 12 also includes an example “margin” of three inches on an example plumbing wall and 1 ½ inches on an example partition wall. The margin allows the non-grid compliant wall sections to fit into the grid environment with an unused void between the walls and the next normal grid line. Adjacent rooms or components then comply with the open grid line leaving the space between as simply an added space. The margin allowance is a method for ensuring that the grid rules remain consistent even when certain assemblies or parts don’t use all of the standard (e.g., 3 inch) micro-grid spatial allowance.

The embodiment shown in FIG. 12 uses a micro-grid that is six inches by six inches and sub-grids of three inches by three inches, one and a half inches by one and a half inches, and three quarters of an inch by three quarters of an inch Embodiments are not limited to grids having these dimensions as any other dimensions can also be implemented by exemplary embodiments. For example, the micro-grid may be one foot by one foot, or nine inches by nine inches, or five inches by five inches, or any other dimension, with sub-grids having dimensions that are half those of the micro-grids. In addition, more or fewer than three levels of sub-grids may be implemented by one or more embodiments of the present invention.

The micro grid rules shown in FIG. 12 control and govern the placement and configuration of rooms (bathroom, kitchens, closets, laundry, mechanical, bedrooms, etc.) from the rooms library 420 to be organized and configured into the macro grid compositions through, for example, the architectural design workstation 708.

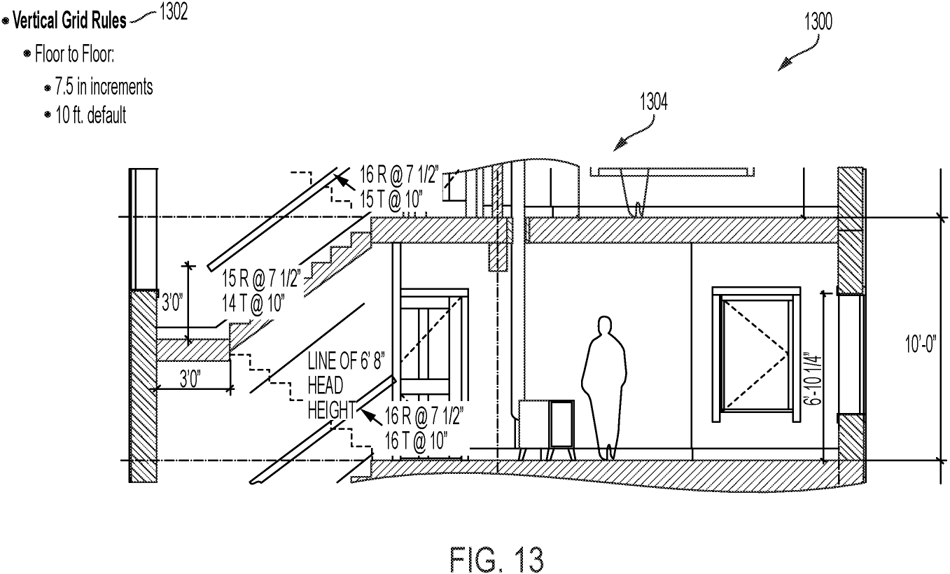

Turning now to FIG. 13, a schematic illustration 1300 of a vertical macro grid 1304 and vertical grid rules 1302 is generally shown in accordance with one or more embodiments of the present invention. The vertical macro grid 1304 shown in FIG. 13 may be displayed to a user for placing objects via, for example, one of the end user design tools 408. The vertical grid shown in FIG. 13 specifies that a distance from a floor on one story to a floor on the next story is at seven and a half inch increments, and that the default distance from a floor on one story to a floor on the next story is ten feet. Each component, when governed by the vertical grid, interacts with the vertical grid under node rules for that component. For example, windows and doors are typically brought to the grid by their top jam height; fixtures by a center height, and stairs by the top of subfloor height. Embodiments of the present invention are not limited to vertical grids with the increments and default distances shown in FIG. 13, as any increments and default distances can be implemented by embodiments of the present invention.

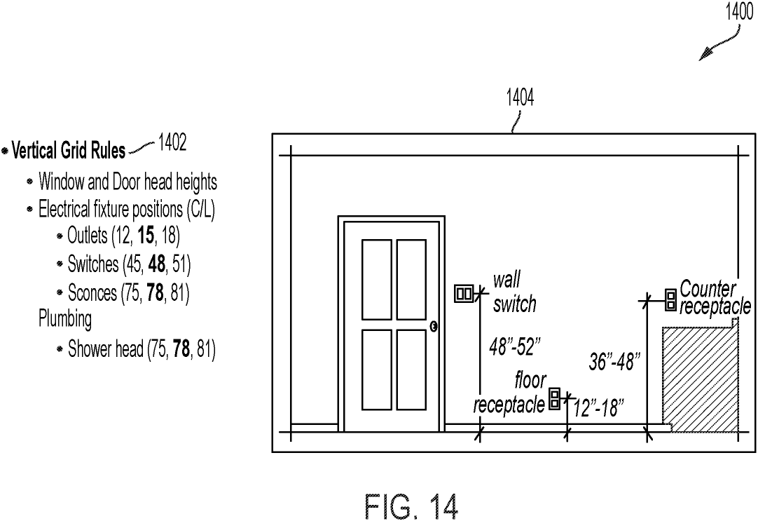

Turning now to FIG. 14, a schematic illustration 1400 of a vertical micro grid 1404 having fixed increments specified by vertical grid rules 1402 is generally shown in accordance with one or more embodiments of the present invention. The vertical micro grid 1404 shown in FIG. 14 may be displayed to a user for placing objects via, for example, one of the end user design tools 408. The vertical micro grid 1404 follows the same rules as a horizontal micro grid (e.g., micro grid 1204 of FIG. 12) and governs similar components such as cabinet and door heights, window head heights, wall heights, floor-to-floor dimensions, etc. It is also used to govern the positions of fixtures such as, but not limited to electrical outlets, switches, lights, and plumbing fixtures. As shown in the examples in FIG. 14, electrical outlets can be placed at twelve, fifteen, or eighteen inches above the floor; switches can be placed at forty-five, forty-eight, or fifty-one inches above the floor; scones at seventy-five, seventy-eight, or eighty-one inches above the floor; and shower heads at seventy-five, seventy-eight, or eighty-one inches above the floor. Other dimensional increments can also be allowed, but all the chosen options will be based on a 3-inch increment. Embodiments of the present invention are not limited to vertical grids with the increments or the rules and attributes shown in FIG. 14, as any increments, rules, and attributes can be implemented by embodiments of the present invention.

In accordance with one or more embodiments of the present invention, bathrooms, kitchens, stairs, and storage locations in a house are defined as “dominant” areas, meaning that elements placed within those spaces must adhere strictly to the grid lines. Mechanically intensive spaces most benefit from standardization of dimensions and positions to aid in efficient manufacturing of rooms in which plumbing pipes, electrical wires and boxes, ventilation ducts, etc. can, for example, be fabricated in advance of on-site assembly as 2D walls, floors, ceilings, etc. or 3D volumetric “pods.” Halls can be defined as held spaces that must meet certain code requirements, but also may have adjacent margins, allowing hall spaces to be dimensionally increased, but never decreased to be less than the design requirement Bedrooms, dining rooms, and living rooms can be “recessive” meaning that the system can accept off-grid margins for elements placed within these spaces. The “recessive” spaces are less mechanically intense and have lower benefit for complete off-site manufacturing of the elements that define or are housed within the space therefore added or decreased dimensions from margins within fixed increments can be tolerated.

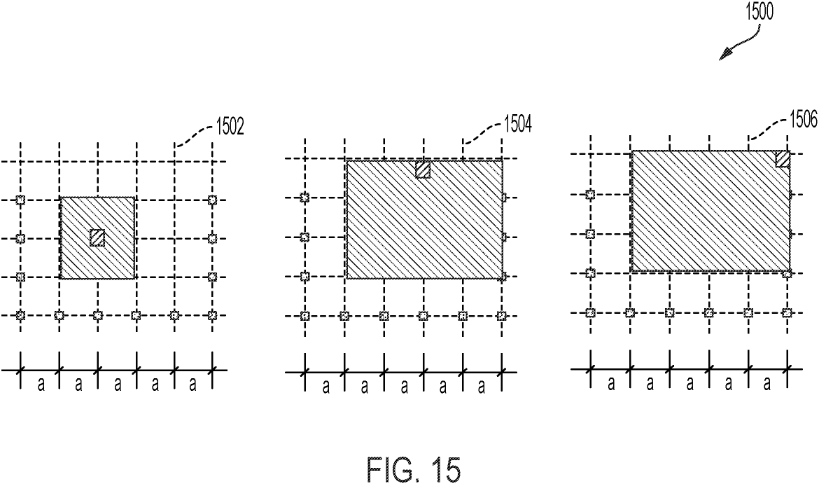

Turning now to FIG. 15, a schematic illustration 1500 of node insertion points is generally shown in accordance with one or more embodiments of the present invention. FIG. 15 includes an example of center line node 1502 inserted at a center line, a center line edge node 1504 inserted at a center line edge, and an edge node 1506 inserted at an edge. The nodes can be used both to adjust dimension and also to place objects, thus providing a bi-functional system “fit” for accuracy and efficiency.

One or more embodiments of the present invention include a variety of different types of customizable rules and attributes that are used in conjunction with the grid when facilitating (by a building design tool such as OBCAD) the design and configuration of buildings or portions of buildings. In the following example, the terms rules and attributes can include but are not limited to the options 208 and attributes 206 previously described in reference to FIG. 2. In addition, the options 208 and attributes 206 can include but are not limited to the rules and attributes described in the below example.

Building components, or objects, can be made available to the design process (e.g., they can be available for placement in the grid) based on the rules and attributes. In accordance with one or more embodiments of the present invention, when the rules associated with a component are satisfied and its attributes are among those selected or filtered, then that component is exposed (e.g., made available) to the current design step (it can be place in the grid), otherwise that component remains hidden (it is not available for placement in the grid). In addition, rules and attributes play a role in verifying that a proposed design is appropriate from a number of aspects. In accordance with one or more embodiments of the present invention, rules are implemented by program modules designed to detect or enforce a particular condition or set of conditions. Selection rules can be automatic and can operate continuously during the design phase (e.g., while the user is modifying or placing objects in the grid). Validation rules can generate warning or error messages to identify problems in the design. Validation rules can be invoked at any time during the design phase, and in accordance with one or more embodiments must run to completion without errors before the project can enter the production

Examples of selection rules include but are not limited to intellectual property rules, edge rules, application rules, and/or location rules. Intellectual property rules can apply to component suites, when a manufacturer has a room design (e.g., a bathroom or kitchen design) that is available but does not allow substitutions. In addition, proprietary designs such as distributor/showroom packages and architect designs may be available to only the provider’s employees. Edge rules enforce components only being available for selection if all top, bottom, left, and right edge rules are satisfied. For a wall component for example, side edge rules may restrict use to butt, corner, tee, or structural timber connections; bottom edge rules may restrict placement on footings, floor system, or another wall; and top edge rules may restrict placement to support for a roof system, floor system, insulated attic, or another wall. Application rules may restrict object, or component, availability to particular applications. For example, a bedroom may be eligible for placement in any served zone, whereas kitchens, baths, and equipment rooms may be restricted to service zones. Location rules can guide the placement of components with respect to the location of other components and can include a dominance hierarchy, bounding boxes, and service planes.

Example of validation rules include but are not limited to code compliance, energy performance, and/or traffic patterns. Code compliance rules can check for conformance with building, plumbing, electrical, fire, and egress codes. Energy performance validation rules can verify that the home meets selected design targets such as LEEDS, Net Zero, Net Zero Ready, and Passive House. Traffic pattern rules can check for requirements such as every bathroom must be accessible to a bathroom without passing through another room.

In accordance with one or more embodiments of the present invention, attributes or options include passive fields containing descriptive data that can be queried by various system components. Attributes can include but are not limited to source, physical attributes, performance rating and finish. Source attributes can include manufacturer, part number, vendor, and/or price per square foot/each/ or bundle. Physical attributes can include dimensions (e.g., length by width by height, thickness, weight, etc.), material, density (e.g., pounds per square foot), and/or structural properties. Performance rating attributes can include R-value, soundproofing, and/or wear resistance. Finish attributes can include quality (e.g., primed pine, CVG fir, mahogany), style (clapboard, shiplap, board and batten), and application (e.g., wet shower, damp bath, dry).

One or more embodiments of the present invention are implemented utilizing hardware and/or software executing on a computing device such as, but not limited to a laptop device 54C, a smartphone 54A and/or a stationary personal computer 54B as shown in FIG. 16. For example, a smartphone of a client may include the software and hardware required to allow the client to perform the actions described herein related to the client, and a laptop device of a practitioner may include the software and hardware required to allow the practitioner to perform the actions described herein related to the practitioner. In addition, these devices may communicate with each other via a network such as, but not limited to, the cloud network 50 shown in FIG. 16.

It is understood in advance that although this disclosure describes a digital platform for a design and build process in reference to cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service’s provider.

Broad network access: capabilities are available over a network and accessed through standard mechanisms that promote use by heterogeneous thin or thick client platforms (e.g., mobile phones, laptops, and PDAs).

Resource pooling: the provider’s computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider’s applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. In essence, cloud computing is an infrastructure made up of a network of interconnected nodes.

Referring now to FIG. 16, an illustrative cloud computing environment 1600 is depicted. As shown, cloud computing environment 1600 comprises a network 50 made up of one or more cloud computing nodes 10 with which local computing devices used by cloud consumers, such as, for example, laptop device 54C, smartphone 54A, in car (or other device) computer 54N, and personal computer 54B may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment to offer infrastructure, platforms and/or software as services for which a cloud consumer does not need to maintain resources on a local computing device. It is understood that the types of computing devices 54 shown in FIG. 16 are intended to be illustrative only and that computing nodes 10 and the cloud computing environment shown in FIG. 16 can communicate with any type of computerized device over any type of network and/or network addressable connection (e.g., using a web browser).

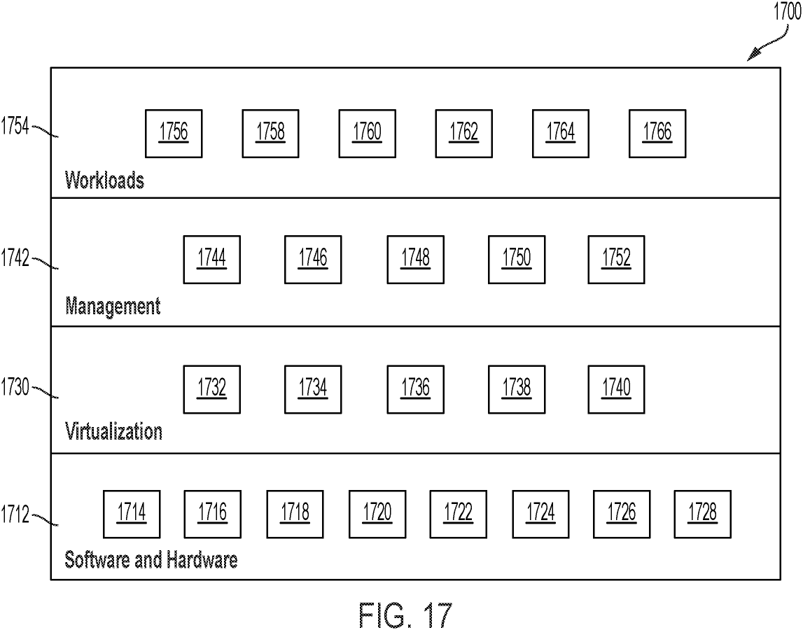

Referring now to FIG. 17, a set of functional abstraction layers provided by the cloud computing environment of FIG. 16 is shown. It should be understood in advance that the components, layers, and functions shown in FIG. 17 are intended to be illustrative only and embodiments of the invention are not limited thereto. As depicted, the following layers and corresponding functions are provided: hardware and software layer 1712 includes hardware and software components. Examples of hardware components include: mainframes 1714; RISC (Reduced Instruction Set Computer) architecture based servers 1716; servers 1718; blade servers 1720; storage devices 1722; and networks and networking components 1724. In some embodiments, software components include network application server software 1726 and database software 1728; virtualization layer 1730 provides an abstraction layer from which the following examples of virtual entities may be provided: virtual servers 1732; virtual storage 1734; virtual networks 1736, including virtual private networks; virtual applications and operating systems 1738; and virtual clients 1740.

In one example, management layer 1742 may provide the functions described below. Resource provisioning 1744 provides dynamic procurement of computing resources and other resources that are utilized to perform tasks within the cloud computing environment. Metering and pricing 1746 provide cost tracking as resources are utilized within the cloud computing environment, and billing or invoicing for consumption of these resources. In one example, these resources may comprise application software licenses. Security provides identity verification for cloud consumers and tasks, as well as protection for data and other resources. User portal 1748 provides access to the cloud computing environment for consumers and system administrators. Service level management 1750 provides cloud computing resource allocation and management such that required service levels are met. Service Level Agreement (SLA) planning and fulfillment 1752 provides pre-arrangement for, and procurement of, cloud computing resources for which a future requirement is anticipated in accordance with an SLA.

Workloads layer 1754 provides examples of functionality for which the cloud computing environment may be utilized. Examples of workloads and functions which may be provided from this layer include: mapping and navigation 1756; software development and lifecycle management 1758; virtual classroom dedication delivery 1760; data analytics processing 1762; transaction processing 1764; and design and build digital platforms 1766.

Turning now to FIG. 18, a schematic illustration of a system 1800 is depicted upon which aspects of one or more embodiments of an OBCAD digital platform may be implemented. In an embodiment, all or a portion of the system 1800 may be incorporated into one or more of the processors, workstations, and/or engines described herein. In one or more exemplary embodiments, in terms of hardware architecture, as shown in FIG. 18, the computer 1801 includes a processing device 1805 and a memory 1810 coupled to a memory controller 1815 and an input/output controller 1835. The input/output controller 1835 can be, for example, but not limited to, one or more buses or other wired or wireless connections, as is known in the art. The input/output controller 1835 may have additional elements, which are omitted for simplicity, such as controllers, buffers (caches), drivers, repeaters, and receivers, to enable communications. Further, the computer 1801 may include address, control, and/or data connections to enable appropriate communications among the aforementioned components.

In one or more exemplary embodiments, a keyboard 1850 and mouse 1855 or similar devices can be coupled to the input/output controller 1835. Alternatively, input may be received via a touch-sensitive or motion sensitive interface (not depicted). The computer 1801 can further include a display controller 1825 coupled to a display 1830.

The processing device 1805 is a hardware device for executing software, particularly software stored in secondary storage 1820 or memory 1810. The processing device 1805 can be any custom made or commercially available computer processor, a central processing unit (CPU), an auxiliary processor among several processors associated with the computer 1801, a semiconductor-based microprocessor (in the form of a microchip or chip set), a macro-processor, or generally any device for executing instructions.

The memory 1810 can include any one or combination of volatile memory elements (e.g., random access memory (RAM, such as DRAM, SRAM, SDRAM, etc.)) and nonvolatile memory elements (e.g., ROM, erasable programmable read only memory (EPROM), electronically erasable programmable read only memory (EEPROM), flash memory, programmable read only memory (PROM), tape, compact disc read only memory (CD-ROM), flash drive, disk, hard disk drive, diskette, cartridge, cassette or the like, etc.). Moreover, the memory 1810 may incorporate electronic, magnetic, optical, and/or other types of storage media. Accordingly, the memory 1810 is an example of a tangible computer readable storage medium 1840 upon which instructions executable by the processing device 1805 may be embodied as a computer program product. The memory 1810 can have a distributed architecture, where various components are situated remote from one another, but can be accessed by the processing device 1805.

The instructions in memory 1810 may include one or more separate programs, each of which comprises an ordered listing of executable instructions for implementing logical functions. In the example of FIG. 18, the instructions in the memory 1810 include a suitable operating system (OS) 1811 and program instructions 1816. The operating system 1811 essentially controls the execution of other computer programs and provides scheduling, input-output control, file and data management, memory management, and communication control and related services. When the computer 1801 is in operation, the processing device 1805 is configured to execute instructions stored within the memory 1810, to communicate data to and from the memory 1810, and to generally control operations of the computer 1801 pursuant to the instructions. Examples of program instructions 1816 can include instructions to implement the processing described herein in reference to FIGS. 1-17.

The computer 1801 of FIG. 18 also includes a network interface 1860 that can establish communication channels with one or more other computer systems via one or more network links. The network interface 1860 can support wired and/or wireless communication protocols known in the art. For example, when embodied in a user system, the network interface 1860 can establish communication channels with an application server.

In accordance with one or more embodiments of the present invention, display 1830 is a display screen on a smartphone, and the keyboard 1850 and mouse 1855 are replaced by the touchscreen interface of the smartphone.

It will be appreciated that aspects of the present invention may be embodied as a system, method, or computer program product and may take the form of a hardware embodiment, a software embodiment (including firmware, resident software, micro-code, etc.), or a combination thereof. Furthermore, aspects of the present invention may take the form of a computer program product embodied in one or more computer readable medium(s) having computer readable program code embodied thereon.

One or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In one aspect, the computer readable storage medium may be a tangible medium containing or storing a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof A computer readable signal medium may be any computer readable medium that is not a computer readable storage medium and that can communicate, propagate, or transport a program for use by or in connection with an instruction execution system, apparatus, or device.

The computer readable medium may contain program code embodied thereon, which may be transmitted using any appropriate medium, including but not limited to wireless, wireline, optical fiber cable, RF, etc., or any suitable combination of the foregoing. In addition, computer program code for carrying out operations for implementing aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user’s computer, partly on the user’s computer, as a stand-alone software package, partly on the user’s computer and partly on a remote computer or entirely on the remote computer or server.

It will be appreciated that aspects of the present invention are described herein with reference to flowchart illustrations and/or block diagrams of methods, apparatus (systems) and computer program products according to embodiments of the invention. It will be understood that each block or step of the flowchart illustrations and/or block diagrams, and combinations of blocks or steps in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

In addition, some embodiments described herein are associated with an “indication”. As used herein, the term “indication” may be used to refer to any indicia and/or other information indicative of or associated with a subject, item, entity, and/or other object and/or idea. As used herein, the phrases “information indicative of” and “indicia” may be used to refer to any information that represents, describes, and/or is otherwise associated with a related entity, subject, or object. Indicia of information may include, for example, a code, a reference, a link, a signal, an identifier, and/or any combination thereof and/or any other informative representation associated with the information. In some embodiments, indicia of information (or indicative of the information) may be or include the information itself and/or any portion or component of the information. In some embodiments, an indication may include a request, a solicitation, a broadcast, and/or any other form of information gathering and/or dissemination.

Numerous embodiments are described in this patent application, and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognize that the disclosed invention(s) may be practiced with various modifications and alterations, such as structural, logical, software, and electrical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise.

Devices that are in communication with each other need not be in continuous communication with each other, unless expressly specified otherwise. On the contrary, such devices need only transmit to each other as necessary or desirable, and may actually refrain from exchanging data most of the time. For example, a machine in communication with another machine via the Internet may not transmit data to the other machine for weeks at a time. In addition, devices that are in communication with each other may communicate directly or indirectly through one or more intermediaries.

A description of an embodiment with several components or features does not imply that all or even any of such components and/or features are required. On the contrary, a variety of optional components are described to illustrate the wide variety of possible embodiments of the present invention(s). Unless otherwise specified explicitly, no component and/or feature is essential or required.

Further, although process steps, algorithms or the like may be described in a sequential order, such processes may be configured to work in different orders. In other words, any sequence or order of steps that may be explicitly described does not necessarily indicate a requirement that the steps be performed in that order. The steps of processes described herein may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to the invention, and does not imply that the illustrated process is preferred.

“Determining” something can be performed in a variety of manners and therefore the term “determining” (and like terms) includes calculating, computing, deriving, looking up (e.g., in a table, database or data structure), ascertaining and the like.

It will be readily apparent that the various methods and algorithms described herein may be implemented by, e.g., appropriately and/or specially-programmed general purpose computers and/or computing devices. Typically, a processor (e.g., one or more microprocessors) will receive instructions from a memory or like device, and execute those instructions, thereby performing one or more processes defined by those instructions. Further, programs that implement such methods and algorithms may be stored and transmitted using a variety of media (e.g., computer readable media) in a number of manners. In some embodiments, hard-wired circuitry or custom hardware may be used in place of, or in combination with, software instructions for implementation of the processes of various embodiments. Thus, embodiments are not limited to any specific combination of hardware and software.

A “processor” generally means any one or more microprocessors, CPU devices, GPU devices, computing devices, microcontrollers, digital signal processors, or like devices, as further described herein. A CPU typically performs a variety of tasks while a GPU is optimized to display images.

Where databases are described, it will be understood by one of ordinary skill in the art that (i) alternative database structures to those described may be readily employed, and (ii) other memory structures besides databases may be readily employed. Any illustrations or descriptions of any sample databases presented herein are illustrative arrangements for stored representations of information. Any number of other arrangements may be employed besides those suggested by, e.g., tables illustrated in drawings or elsewhere. Similarly, any illustrated entries of the databases represent exemplary information only; one of ordinary skill in the art will understand that the number and content of the entries can be different from those described herein. Further, despite any depiction of the databases as tables, other formats (including relational databases, object-based models and/or distributed databases) could be used to store and manipulate the data types described herein. Likewise, object methods or behaviors of a database can be used to implement various processes, such as the described herein. In addition, the databases may, in a known manner, be stored locally or remotely from a device that accesses data in such a database.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

Terms such as processor, controller, computer, DSP, FPGA are understood in this document to mean a computing device that may be located within an instrument, distributed in multiple elements throughout an instrument, or placed external to an instrument.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

The term “about” is intended to include the degree of error associated with measurement of the particular quantity based upon the equipment available at the time of filing the application. For example, “about” can include a range of ± 8% or 5%, or 2% of a given value.

1-20. (canceled)

21. A building design method comprising:
obtaining, by a processor, an object to be placed in a grid that represents at least a subset of a building, the object having an object type and one or more characteristics, and the grid comprising grid lines;
selecting, by the processor, a grid segment size of the grid lines based at least in part on one or both of default grid dimensions and regression rules, the selecting comprising:
assigning the grid segment size based at least in part on the object type, wherein an object having an object type of infill is assigned a smaller grid segment size than an object having an object type of shell;
determining, based on the one or more characteristics, whether the grid segment size should be modified; and
modifying the grid segment size, using a logical regression, based on determining that the grid segment size should be modified;
placing, by the processor, the object in a location in the grid based at least in part on instructions received from the user and on placement rules enforced by the grid; and
displaying, by the processor, the grid to the user.

22. The method of claim 21, further comprising generating one or both of a building information model (BIM) and a building production model (BPM) based at least in part on contents of the grid.

23. The method of claim 21, wherein the object type of the object is shell and the grid is a macro grid.

24. The method of claim 21, wherein the object type of the object is infill and the grid is a micro grid.

25. The method of claim 21, wherein the location is between the grid lines, thereby providing a margin management adjustment.

26. The method of claim 21, wherein the object is selected from a library of objects that conform to specified increments of length, width, and height.

27. The method of claim 26, wherein a description of the object is received in a first format, a description of another object is received in a second format different than the first format, and one or more templates are utilized to generate descriptions of the objects in a standard format different than the first and second format prior to adding the objects to the library.

28. The method of claim 21, wherein the obtaining, selecting, placing, and displaying are repeated for at least one other object.

29. The method of claim 21, wherein the placing is further based at least in part on a location of another object previously placed in the grid.

30. The method of claim 21, wherein the placing causes one or both of a position or a dimension of another object previously placed in the grid to adjust accordingly.

31. The method of claim 21, wherein the placement rules vary based on one or both of the object type and the characteristics of the object.

32. The method of claim 21, wherein the dimension of the object being placed in the grid is based on one or more of standard dimensions enforced by the grid, the object type, or the characteristics of the object.

33. The method of claim 21, wherein the grid is three-dimensional.

34. The method of claim 21, wherein the grid lines can be turned on or off during the displaying.

35. A building design system comprising:
one or more processors for executing computer readable instructions, the computer readable instructions controlling the one or more processors to perform operations comprising:
obtaining an object to be placed in a grid that represents at least a subset of a building, the object having an object type and one or more characteristics, and the grid comprising grid lines;
selecting a grid segment size of the grid lines based at least in part on one or both of default grid dimensions and regression rules, the selecting comprising:
assigning the grid segment size based at least in part on the object type, wherein an object having an object type of infill is assigned a smaller grid segment size than an object having an object type of shell;
determining, based on the one or more characteristics, whether the grid segment size should be modified; and
modifying the grid segment size, using a logical regression, based on determining that the grid segment size should be modified;
placing the object in a location in the grid based at least in part on instructions received from the user and on placement rules enforced by the grid; and
displaying the grid to the user.

36. The system of claim 35, wherein when the object type of the object is shell the grid is a macro grid and when the object type of the object is infill the grid is a micro grid.

37. The system of claim 35, wherein the placement rules vary based on one or both of the object type and the characteristics of the object.

38. The system of claim 35, wherein the dimension of the object being placed in the grid is based on one or more of standard dimensions enforced by the grid, the object type, or the characteristics of the object.

39. The system of claim 35, wherein the grid is three-dimensional.

40. A computer program product comprising a computer readable storage medium having program instructions embodied therewith, the program instructions executable by one or more processors to cause the one or more processors to perform building design operations comprising:
obtaining, by a processor, an object to be placed in a grid that represents at least a subset of a building, the object having an object type and one or more characteristics, and the grid comprising grid lines;
selecting a grid segment size of the grid lines based at least in part on one or both of default grid dimensions and regression rules, the selecting comprising
assigning the grid segment size based at least in part on the object type, wherein an object having an object type of infill is assigned a smaller grid segment size than an object having an object type of shell;
determining, based on the one or more characteristics, whether the grid segment size should be modified; and
modifying the grid segment size, using a logical regression, based on determining that the grid segment size should be modified;
placing the object in a location in the grid based at least in part on instructions received from the user and on placement rules enforced by the grid; and
displaying the grid to the user.
